(19) United States
(12) Patent Application Publication
(10) Pub. No.: US 2005/0006561 A1
(43) Pub. Date: Jan. 13, 2005

(54) Image sensing module

(76) Inventors: Yi-Shiuan Chiou, Chu-Bei City (TW); Chi-Wen Chen, Chu-Bei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/699,928

(22) Filed: Nov. 4, 2003

(30) Foreign Application Priority Data
Jul. 8, 2003 (TW) 92212486

(51) Int. Cl. H01L 27/00; H01J 5/16

(52) U.S. Cl. 250/208.1; 250/216

(57) ABSTRACT

An image sensing module comprises an imaging sensing component and a lens arranged on the image sensing component. The lens is fastened with the image sensing component through adhesion or by using a fastener. Through the function of the lens, incident light will pass through the lens and then be detected by the photosensitive plane of the image sensing component. The size and shape of the lens are properly chosen to adjust the optical system used by the image sensing module. The image sensing module can apply to digital image products such as scanners and digital still cameras. Image distortion can be effectively improved, and the volume of applicable digital image products can be properly shrunk, hence accomplishing the effect of miniaturization of digital image products.

### FIELD OF THE INVENTION

The present invention relates to an image sensing module and, more particularly, to an image sensing module, which combines an image sensing component and a lens together to improve the optical imaging quality and also shrink the size of applicable digital image products.

### BACKGROUND OF THE INVENTION

In this information age, digital image products have gone deep into every people's life. Electronic products such as digital still cameras or scanners have substantially changed the lift styles of common people. Under the restriction of limited resources and space, miniaturization of electronic products is the inevitable trend. Digital image products are no exception. Only continually renewed and shrunk digital image products can seize the eyes of customers.

FIG. 1 shows a conventional desktop flatbed scanning optical system, wherein a light source 10 is used to illuminate a glass plane 12 having a document 14 to be scanned thereon. Light reflected by the document 14 is guide by a set of mirrors to a lens 18. Next, light passing through the lens 18 is guide to a charge coupled device (CCD) detector 20, which is used to record the image of the document 14. When the size of the scanner is to be shrunk with unchanged optical resolution and CCD detector's size, it is usually necessary to shorten the optical imaging path and shrink the scanner's volume. In order to let the scanned image be completely imaged on the CCD detector 20, it is necessary to enlarge the visual angle of the lens 18 for properly adjusting the magnification ratio of imaging. However, imaging distortion may easily arise if the visual angle of the lens is too large. If a lens 182 is to be added on the imaging path to solve the above problem of image distortion, the scanner's volume will be hard to shrink, and the difficulty of accurately assembling the optical scanning system will increase, as shown in FIG. 2.

### SUMMARY AND OBJECT OF THE PRESENT INVENTION

The primary object of the present invention it to provide an image sensing module, wherein a lens of appropriate shape and size is fixed on an image sensing component to save the space for arranging the lens and the assembly step and also shrink the size of digital image products using this image sensing module.

Another object of the present invention is to provide an image sensing module to adjust and improve the imaging quality of applicable digital image products.

According to the present invention, an image sensing module comprises an image sensing component and a lens arranged on the image sensing component. The lens is fixed with the image sensing component by means of adhesion or by using a fastener. The size and shape of the lens are properly chosen to adjust the optical system of digital image products using this image sensing module, thereby improving the imaging quality and shrink the size.

The various objects and advantages of the present invention will be more readily understood from the following detailed description when read in conjunction with the appended drawings, in which:

### BRIEF DESCRIPTION OF DRAWINGS

FIG. 1 is an imaging diagram of a conventional scanner;

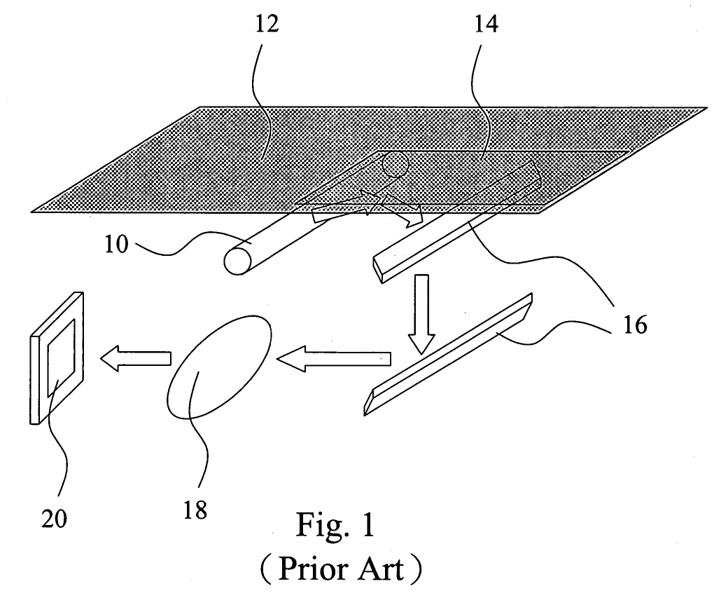

FIG. 2 is another imaging diagram of a conventional scanner;

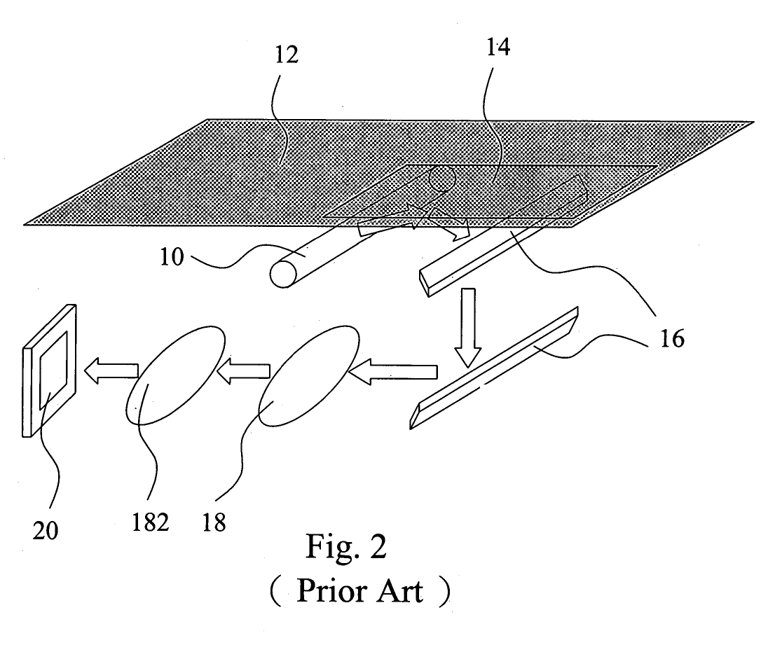

FIG. 3 is a diagram of an image sensing module of the present invention; and

FIG. 4 is a diagram of a scanner making use of the present invention.

### DETAILED DESCRIPTION OF PREFERRED EMBODIMENTS

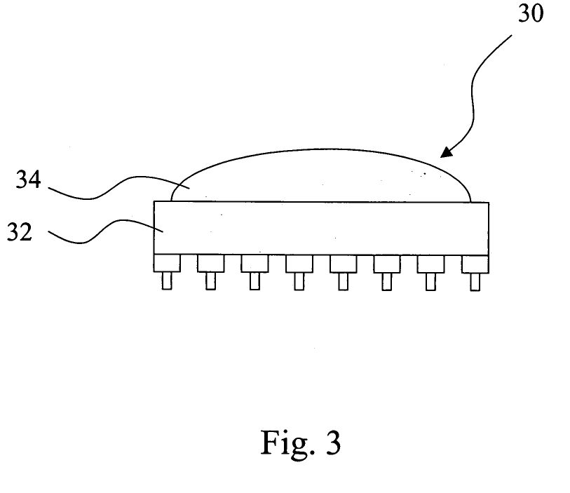

The present invention provides an image sensing module, wherein an image sensing module and a lens is combined together to shrink the volume of applicable digital image products without any sacrifice of the imaging quality. As shown in FIG. 3, an image sensing module 30 comprises an image sensing component 32 and a lens 34 arranged thereon. Incident light passes through the lens 34 and is then detected by the photosensitive plane of the image sensing component 32. The shape and size of the lens 34 are properly chosen to adjust the imaging effect and quality. The lens 34 is adhered on the image sensing component 32. The image sensing component 32 can be a charge coupled device (CCD) detector or a complementary metal oxide semiconductor (CMOS) detector.

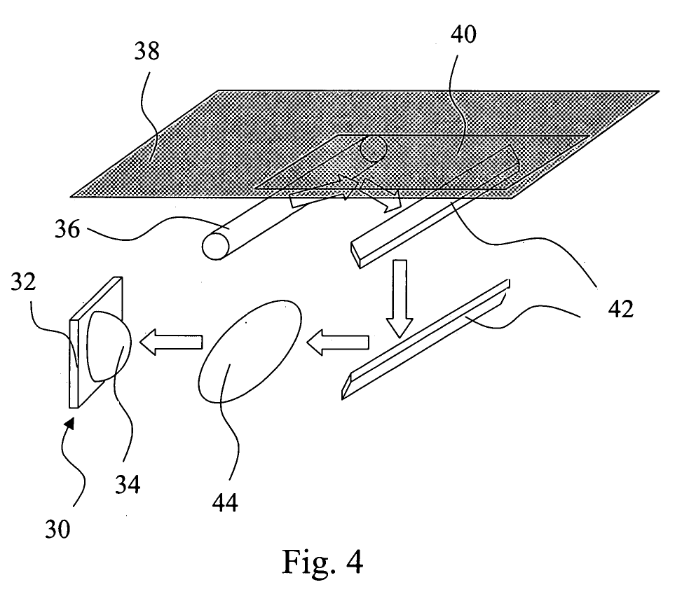

As shown in FIG. 4, a cold light source 36 illuminates light to a glass plane 38 with a document 40 to be scanned thereon. Light is reflected by the document 40 to a set of mirrors 42. The positions of the set of mirrors 42 are properly arranged and calibrated to ensure that light reflected by the document 40 be accurately guided and pass through a lens 44. Light passing through the lens 44 will be focused and imaged on the image sensing module 30 of the present invention. The image sensing module 30 of the present invention comprises an image sensing component 32 and a lens 34 arranged on the image sensing component 32. The size and shape of the lens 34 are properly chosen to match the optical system used by the image sensing module 30 of the present invention. Therefore, when the imaging path of the scanner is shortened, light can still be imaged on the photosensitive plane of the image sensing component 32 through the function of the lens 34 to avoid image distortion. Moreover, the volume of the scanner can be shrunk through shortening the imaging path, hence accomplishing the effect of miniaturization of product.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

1. An image sensing module comprising:
an image sensing component whose one surface is a photosensitive plane; and
a lens fixed on said image sensing component, external incident light passing through said lens and then being detected by said photosensitive plane of said image sensing component.

2. The image sensing module as claimed in claim 1, wherein said image sensing component is a CCD detector or a CMOS detector.

3. The image sensing module as claimed in claim 1, wherein said lens is adhered on said image sensing component.

4. The image sensing module as claimed in claim 1, wherein said lens is fixed on said image sensing component by using a fastener.

5. The image sensing module as claimed in claim 1, wherein said lens of appropriate shape and size is chosen to combine with said image sensing component for adjusting the optical system used by said image sensing module.
